(19) United States
(12) Patent Application Publication
(10) Pub. No.: US 2008/0076229 A1
(43) Pub. Date: Mar. 27, 2008

(54) Method to form decoupling capacitors on IC chip and the structure thereof

(76) Inventors: Jason Mao, Shanghai (CN); James Yu Peng, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/527,488

(22) Filed: Sep. 27, 2006

(51) Int. Cl. H01L 21/20

(52) U.S. Cl. 438/381

(57) ABSTRACT

A method to form decoupling capacitors on an IC chip and the structure thereof includes forming several metal layers on a low-metal-covering-ratio region of the IC chip and connecting these metal layers to the ground, source voltage respectively, in order to form parasite metal capacitors that can be as decoupling capacitors with satisfying the metal covering rules so as to make good use of the IC chip space.

### BACKGROUND OF THE INVENTION

1. Field of the Invention

The present invention relates to a technique of setting decoupling capacitors between the power source and the ground, and more particularly to a method to directly form decoupling capacitors on an IC chip and the structure thereof.

2. Description of the Related Art

With people's need for high-speed data processing and calculating, computer technology makes giant progress. For the framework of computer, not only the scale of IC-chip manufacturing is getting smaller and smaller, but the density of interconnection between each component is getting higher and higher. The density of components on per unit area also is increasing. Therefore, low operating voltage and small oscillation are a common design tendency. However, low operating voltage will be more easily affected by noise, and the sources of theses noise may come from the coupling or crosstalk of the signals, or from the inter-symbol interference (ISI) between two adjacent signals, or from electromagnetic interference (EMI) or electromagnetic compatibility (EMC). Moreover, the most influential source is from the power supply noise, especially the simultaneous switching noises (SSN) that occur when properly several signals open and close at the same time.

For IC chip design, to obviate the power supply noise is often achieved by setting decoupling capacitors. When the locations of setting decoupling capacitors are more close to components, the effects are better. Besides, the larger capacitance is better. However, with the higher and higher packing density of components and wirings, it will be not easy to find sufficient and proper space to set decoupling capacitors.

Therefore, this invention presents a method to form decoupling capacitors on an IC chip and the structure thereof.

### SUMMARY OF THE INVENTION

The present invention is to provide a method to form decoupling capacitors on an IC chip and the structure thereof, which not only satisfies the metal covering rules, but make good use of IC chip space to make capacitors as largely as possible.

Another, the present invention is to provide a method to form decoupling capacitors on an IC chip and the structure thereof, which is able to obtain better effects of obviating power supply noise.

Still another, the present invention is to provide a method to form decoupling capacitors on an IC chip and the structure thereof, which is able to find a location closet to an IC chip so as to place decoupling capacitors.

The present invention presents a method to form decoupling capacitors on an IC chip. This method first forms several metal layers on a low-metal-covering-ratio region of an IC chip, and then connects odd layers/even layers of the metal layers to the ground and connects even layers/odd layers to a source voltage, in order to form parasite metal capacitors, which can be as decoupling capacitors, between the adjacent layers of the metal layers.

Further, this invention also provides a structure, of a decoupling capacitor on an IC chip. The structure comprises several metal layers situated on a low-metal-covering-ratio region of the IC chip, wherein odd layers/even layers are connected to the ground and even layers/odd layers are connected to a source voltage.

To enable the objectives, technical contents, characteristics and accomplishments of the present invention to be more easily understood, the embodiments of the present invention are to be described below in detail in cooperation with the attached drawings.

### BRIEF DESCRIPTION OF THE DRAWINGS

FIG. 1 is a diagram of an embodiment according to the present invention.

FIG. 2 is a diagram illustrating metal capacitor units according to the present invention.

FIG. 3 is a diagram illustrating parasite metal capacitors situated between layers according to the present invention.

### DESCRIPTION OF THE PREFERRED EMBODIMENTS

This invention relates a method to form decoupling capacitors on an IC chip and the structure thereof.

First, explain the circumstances of current IC chips. In most IC-chip design, there are still many chip areas unused. In order to avoid that any nonmetal regions are larger than 3 μm², dummy metal lines are inserted on these low metal density regions to satisfy the rules of certain metal density.

However, these dummy metal lines situated in the nonmetal regions are usually just placed on the nonmetal regions, and there is no practical work. Hence, under the rules of certain metal-covering ratio that IC chips have to obey, parasite metal capacitor units, which can be as decoupling capacitors, are formed at the low metal-covering ratio to satisfy the metal density condition and solve decoupling capacitors what IC chips need.

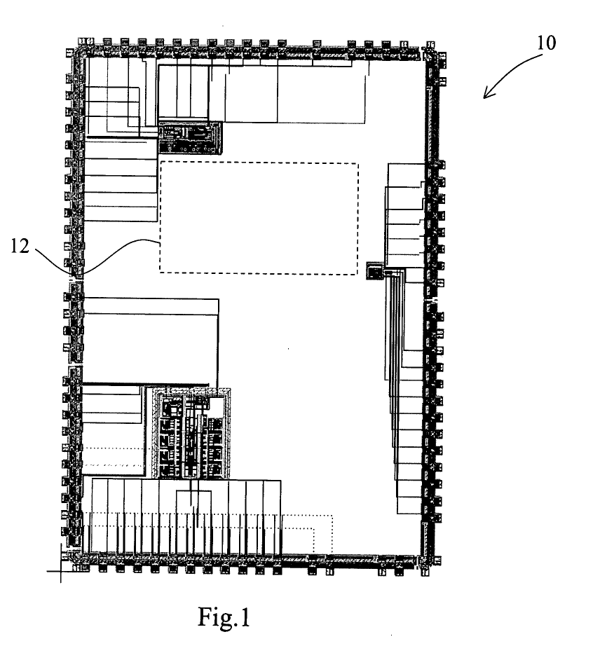

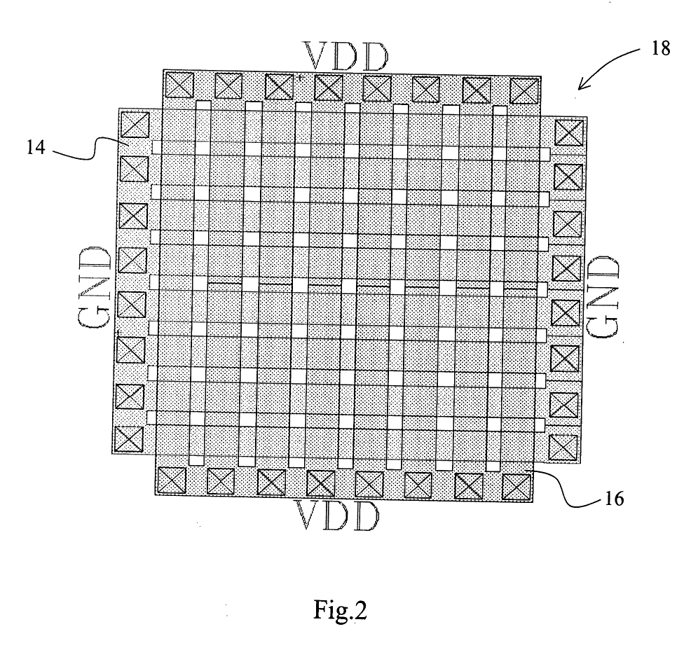

Referring to FIG. 1 and FIG. 2, select a low-metal-covering-ratio region 12 on an IC chip 10. Then, form several dummy metal layers, which appear piled in an interfolding way, on the low-metal-covering-ratio region 12 unaffecting circuits. Each metal layer is constituted by several metal lines. The metal lines of the odd layers arrange in the same form, and the distributions of the metal lines of all odd layers are identical, and only the coordinate of Z axis is different. The even layers are in the same situation. For instance, in FIG. 2 the metal lines of odd layers 14 line horizontally, and those of even layers 16 line vertically. Afterwards, the odd layers 14 of these dummy mental layers which are piled layer-likely are connected to the ground and the even layers 16 are connected to the source voltage, such as in FIG. 2 illustrating several metal capacitor units 18, which can be as decoupling capacitors, formed between the adjacent metal layers. Besides, the odd layers also can be connected to the source voltage and the even layers are connected to the ground.

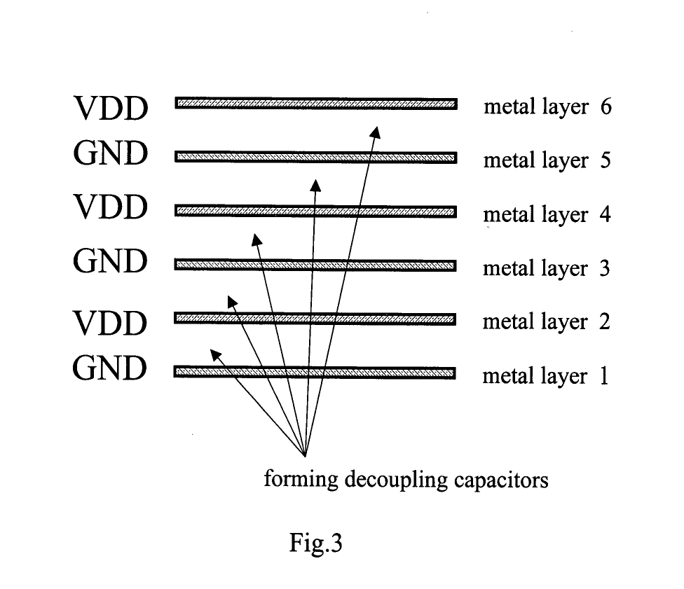

To cite an embodiment, odd layers 1, 3, 5 are connected to the ground, such as shown in FIG. 3, and even layers 2, 4, 6 are connected to the source voltage. Hence, there are five parasite metal capacitors that can be as decoupling capacitors, formed between the metal layer 1 and the metal layer 2, between the metal layer 2 and the metal layer 3, between the metal layer 3 and the metal layer 4, between the metal layer 4 and the metal layer 5, and between the metal layer 5 and the metal layer 6.

In summary, this invention is a method to form decoupling capacitors on an IC chip and the structure thereof. In the manufacturing process of IC chips, each layer has to satisfy the rules of the metal density, and the adjacent metal layers that are as the dummy metal layers are connected to the ground and the source voltage respectively to form several decoupling capacitor units. In this way, this method not only satisfies the metal-covering-ratio rules, but also makes good use of IC-chip space, and makes decoupling capacitors as largely as possible. Further, the location between the decoupling capacitors and IC chip is closer, so the obtained effects of obviating the power supply noise are better.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

What is claimed is:

1. A method to form decoupling capacitors on an IC chip, comprising the steps of:
forming several metal layers on a low-metal-covering-ratio region of the IC chip; and
connecting odd layers/even layers of the metal layers to a ground and connecting even layers/odd layers of the metal layers to a source voltage, so as to form parasite metal capacitors which are as decoupling capacitors between adjacent layers of the metal layers.

2. The method to form decoupling capacitors on IC chip according to claim 1, wherein each of the metal layers comprises several metal lines, and metal lines of the odd layers of the metal layers line horizontally, and metal lines of the even layers of the metal layers line vertically.

3. The method to form decoupling capacitors on IC chip according to claim 1, wherein each of the metal layers comprises several metal lines, and metal lines of the odd layers of the metal layers line vertically, and metal lines of the even layers of the metal layers line horizontally.

4. A decoupling capacitor structure situated on an IC chip, comprising a plurality of metal layers situated on a low-metal-covering-ratio region of the IC chip, wherein odd layers/even layers of the metal layers are connected to a ground, and even layers/odd layers of the metal layers are connected to a source voltage.

5. The decoupling capacitor structure situated on IC chip according to claim 4, wherein each of the metal layers includes several metal lines, and metal lines of the odd layers of the metal layers line horizontally, and metal lines of the even layers of the metal layers line vertically.

6. The decoupling capacitor structure situated on IC chip according to claim 4, wherein each of the metal layers include several metal lines, and metal lines of the odd layers of the metal layers line vertically, and metal lines of the even layers of the metal layers line horizontally.
